(19) United States
(12) Patent Application Publication
(10) Pub. No.: US 2006/0007995 A1
(43) Pub. Date: Jan. 12, 2006

(54) Apparatus for digital data transmission in state of using mobile telecommunication device and the method thereof

(75) Inventor: Kyu Chel Yeon, Seoul (KR)

Correspondence Address: JONATHAN Y. KANG, ESQ.;LEE, HONG, DEGERMAN, KANG & SCHMADEKA, P.C., 14th Floor, 801 S. Figueroa Street, Los Angeles, CA, 90017-5554, US

(73) Assignee: LG Electronics Inc.

(21) Appl. No.: 11/179,392

(22) Filed: Jul. 11, 2005

(30) Foreign Application Priority Data
Jul. 12, 2004 (KR) 10-2004-0053912

(51) Int. Cl. H03K 5/159

(52) U.S. Cl. 375/229

(57) ABSTRACT

Disclosed is an apparatus and a method for digital data transmission by using a mobile communication terminal, including the steps of converting an analog voice signal into a digital signal, the analog voices signal inputted through a microphone; inserting a watermark into the digital voice signal, the watermark including additional information, encoding the digital voice signal having a watermark inserted therein in a way determined by a communication mode, and transmitting the encoded voice signal having the watermark inserted therein.

### CROSS-REFERENCE TO RELATED APPLICATIONS

This application claims the benefit of Korean Application No. P10-2004-0053912, filed on Jul. 12, 2004, which is hereby incorporated by reference as if fully set forth herein.

### BACKGROUND OF THE INVENTION

1. Field of the Invention

The present invention relates to an apparatus and a method for a digital data transmission by using a mobile telecommunication terminal, and more particularly, to a method of transmitting and receiving for inserting/withdrawing digital data into/from a voice signal in a watermark form.

2. Discussion of the Related Art

FIG. 1 illustrates a block diagram showing a process of a conventional voice communication schematically. As illustrated, during voice communication via a conventional mobile phone, an analog voice signal received through a microphone is converted into a digital signal by an analog digital converter (ADC) 11 at a transmitting platform, and then wirelessly transmitted to a transmitter 113 through a voice encoder 112 for compression. A signal received at a receiving member 121 is an encoded signal. The signal transmitted through the receiving member 121 is decoded by the voice decoder 122, and then outputted as an audible sound through a digital analog converter (DAC) 123.

Meanwhile, there are such a method of transmitting a text message from the conventional mobile phone as SMS, Email, and IM (instant message). Excepting a protocol for voice communication, there is a protocol for the SMS, Email, and IM, and the protocol is needed additionally.

When additional information including a text message is sent during voice communication, the information needs to be transmitted through SMS, Email and IM, which are used for a conventional text message. However, a method used for a conventional text message needs a protocol for the text message in addition to a protocol for voice communication. When the text message is transmitted or received during voice communication, a communication channel is additionally needed except voice communication, and therefore a charge for using the text message is additionally demanded in addition to a charge for voice communication.

### SUMMARY OF THE INVENTION

Accordingly, the present invention is directed to an apparatus and a method for digital data transmission that substantially obviates one or more problems due to limitations and disadvantages of the related art.

An object of the present invention is to provide an apparatus and a method for digital data transmission without using an additional protocol during communication by using a mobile communication terminal.

Another object of the present invention is to provide an apparatus and a method for transmitting a text message without an additional charge during communication by using a mobile communication terminal.

A characteristic of the method for the digital data transmission during communication in accordance with the present invention is inserting additional information in a digital type into the voice signal in a watermark form, and then transmitting the signal.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for digital data transmission during communication includes the steps of converting an analog voice signal into a digital signal, the analog voices signal inputted through a microphone; encoding the digital voice signal in a way determined by a communication mode, inserting a watermark into the encoded digital voice signal, the watermark including digital data; and transmitting the encoded voice signal having the watermark inserted therein.

In another aspect of the present invention, an apparatus for transmitting additional information during communication includes an analog-digital converter for converting an analog voice signal into a digital signal, the analog voice signal inputted through a microphone; a voice encoder for creating an encoded voice signal thorough compressing and encoding the voice signal digitized through the analog-digital converter; a watermark inserting member for inserting a watermark into the encoded voice signal; and a transmitter for transmitting the voice signal having the watermark inserted therein.

In another aspect of the present invention, an apparatus for transmitting additional information during communication includes an analog-digital converter for converting an analog voice signal into a digital signal, the analog voice signal inputted through a microphone; a watermark inserting member for inserting a watermark into the voice signal digitized through the analog-digital converter; a voice encoder for creating an encoded voice signal thorough a process of compressing and encoding the voice signal having the watermark inserted therein; and a transmitter for transmitting the voice signal encoded by inserting the watermark therein.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 illustrates a schematic block diagram showing a conventional voice communication process;

FIG. 2 illustrates a block diagram showing a communication process including a structure in accordance with a first embodiment of an apparatus for transmitting additional information during communication in accordance with the present invention;

FIG. 3 illustrates a block diagram showing a communication process including a structure in accordance with a second embodiment of an apparatus for transmitting additional information during communication in accordance with the present invention;

FIG. 4 illustrates a flow chart showing a process in accordance with a first embodiment of a method for transmitting additional information during communication in accordance with the present invention; and

FIG. 5 illustrates a flow chart showing a process in accordance with a second embodiment of a method for transmitting additional information during communication in accordance with the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, an apparatus and a method for transmitting digital data during communication in accordance with the present invention will be described referring to appended drawings.

As abovementioned, a notable feature of the present invention is that additional information is inserted into a voice signal as a watermark during communication by using a mobile communication terminal, and transmitted. The signal is then received and decoded. In other words, a value to be transmitted is inserted into an original voice signal in a watermark form. A value inserted into a process of encoding a voice needs not to be a harsh grating noise.

The watermark applied to the voice is divided into an encoding process for inserting additional information that is desired to be inserted into the original voice signal, and a decoding process for extracting the inserted signal. In the encoding process, the additional information is inserted into the original voice signal by changing the information into a signal that is unrecognizable by a human. There is a PN sequence or an echo signal as an inserting method. In the decoding process, the PN sequence or the echo signal inserted into the voice signal is extracted. The inserted value in the encoding process is known through the extracted PN sequence or the echo signal.

As an art for filling in the digital watermark into the digital audio signal, the lowest bit (LSB) of a PCM audio signal in 16 bits is used for watermark data. Also used is an art for filling in the additional information into the digital audio signal as the watermark by manipulating a modified Discrete Cosine Transformation (MDCT) coefficient of the compression encoded digital audio signal or a coefficient of a sub band.

In the present invention, the voice is collected by using a microphone in the same method as the transmitting platform in the conventional voice communication, and digitized through the analog-digital converter. The conventional method creates the encoded voice signal by using a digital voice signal directly for the voice encoding.

However, in the present invention, the digital voice signal is used, and watermark insertion and voice encoding are performed so as to create the encoded voice signal with the watermark inserted therein. The encoded voice signal having the watermark inserted therein is transmitted through a conventional transmitter. A block for decoding and encoding the watermark is positioned at a front and rear end of the voice encoder and decoder according to the method of inserting the watermark.

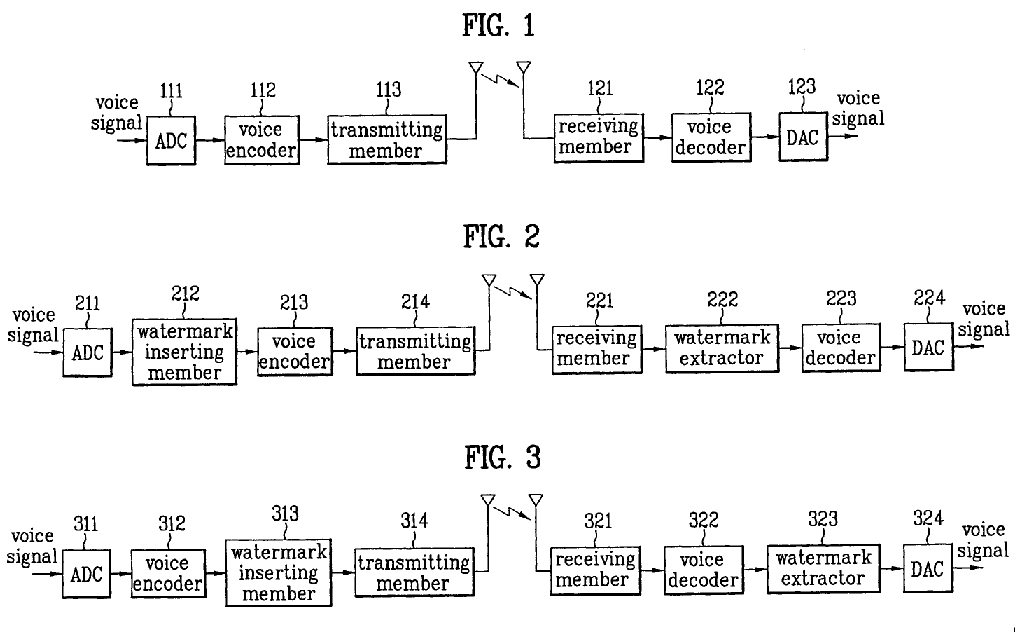

FIG. 2 illustrates a block diagram showing a structure in accordance with a first embodiment of an apparatus for transmitting digital data during communication in accordance with the present invention.

First of all, a part for inserting additional information into the voice signal and transmitting includes an analog digital converter (ADC) 211 for converting an analog voice signal inputted through the microphone into the digital signal, a watermark inserting member 212 for inserting the watermark into the voice signal being digitized through the analog digital converter (ADC) 211, a voice encoder 213 for creating the voice signal encoded through a process of compressing and encoding the voice signal having the watermark inserted therein, and a transmitter 214 for transmitting the voice signal encoded by inserting the watermark. Meanwhile, an apparatus for receiving additional information during communication in accordance with the present invention includes a receiving member 221 for receiving a signal having the additional information inserted therein through an antenna, a watermark extractor 222 for extracting the watermark from the voice signal transmitted through the receiving member 221, a voice decoder 223 for decoding the voice signal, from which the watermark is extracted, into the digital voice signal, and a digital-analog converter (DAC) 224.

FIG. 3 illustrates a block diagram showing a structure in accordance with a second embodiment of an apparatus for transmitting digital data during communication in accordance with the present invention. As illustrated, the apparatus for transmitting digital data in accordance with the second embodiment includes an analog-digital converter 311 for converting the analog voice signal inputted through the microphone into the digital signal, a voice encoder 312 for creating the voice signal encoded through a process of compressing and encoding the voices signal being digitized through the analog-digital converter 311, a watermark inserter 313 for inserting the watermark into the encoded voice signal, and a transmitter 314 for transmitting the voice signal having the watermark inserted therein.

Contrary to the structure of FIG. 2, after encoding the voice, the converted digital data is inserted as the watermark. The structure for decoding voice at the receiving platform, contrary to the illustration of FIG. 2, includes a voice decoder 322 for decoding the encoded voice signal received through the receiving member 321 into the digital voice signal, a watermark extractor 323 for extracting the watermark, and a digital-analog converter 324 for converting the digital voice signal into the analog signal.

‘8-2 The signal is received through the receiving member 321 on a mobile phone of a receiver, and the encoded voice signal having the watermark inserted therein is voice decoded, and the inserted watermark signal is extracted. The additional information is extracted from the received signal by the watermark extractor 323, and the digital voice signal is obtained through the voice decoder 322. The digital voice signal is converted into the analog signal through the digital-analog converter 324 in the same way as the conventional method, and then outputted through a speaker.

Additional information service data commonly used in a recent mobile communication system is inserted in a watermark form into the digital voice signal in accordance with the present invention. The additional information service data being inserted may be a short message service (EMS), an enhanced messaging service (EMS), and a multimedia messaging service (MMS). Transmission data of the multimedia messaging service may be a bell sound, a compressed digital music file (MP3) and animation data embodied at the mobile communication terminal.

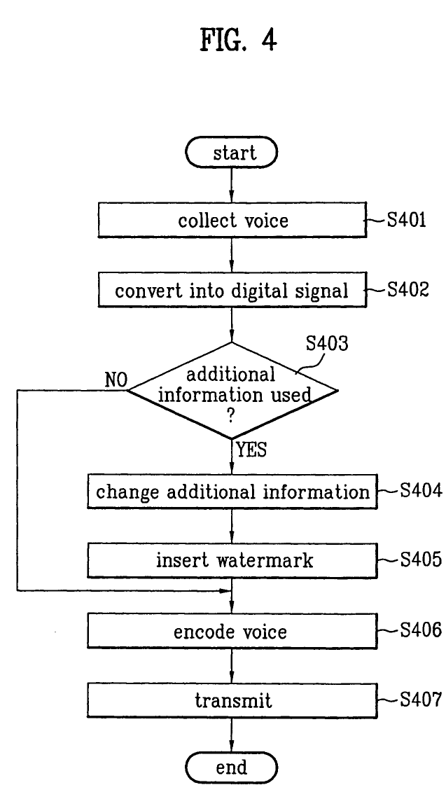

FIG. 4 illustrates a flow chart showing a process in accordance with a first embodiment of an apparatus for transmitting additional information during communication in accordance with the present invention. A voice inputted through the microphone is collected as the voice signal (S401), and the analog voice signal is converted into the digital signal (S402).

When a user needs to transmit the digital data during communication, a signal, for example, for transmitting the digital data is inputted as an interrupt in various forms such as pressing a particular key during communication. In this instance, an input key being used is assembled by a plurality of keys, or a separate menu key may be formed (S403). Accordingly, the signal for transmitting the digital data is inputted (S405) into the voice signal in the watermark form by converting the digital data (S404). As abovementioned, the digital data may include a various kinds of data such as SMS, EMS, and MMS or a character image.

The encoded voice signal having the watermark inserted therein is then transmitted (S407) through the encoding process (S406) for converting the digital voice signal having the watermark inserted therein in a way determined by a communication mode. Only for a general voice communication, a conventional communication process is performed in the same way without a separate transaction. In other words, a wireless voice signal is transmitted through the transmitter by compressing and encoding the voice signal in a digital form.

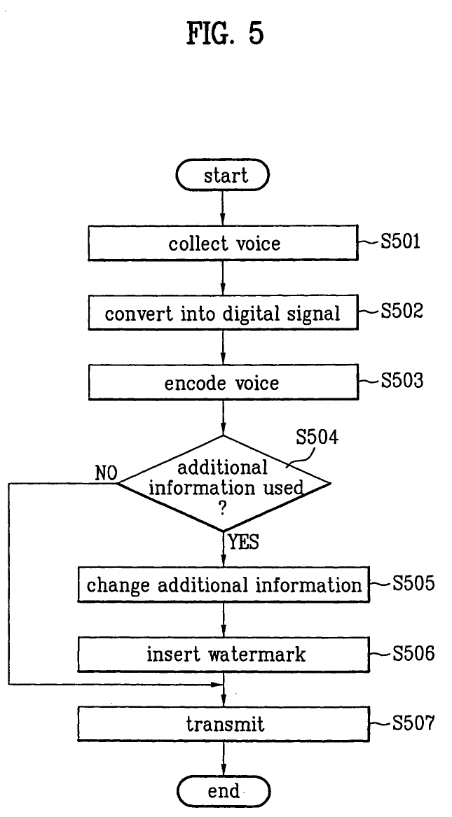

FIG. 5 illustrates a flow chart showing a process in accordance with a second embodiment of a method for transmitting additional information during communication in accordance with the present invention. The voice inputted through the microphone is collected as the analog voice signal (S501), and the analog signal is converted into the digital signal (S502). The voice signal in a digital form is compressed and encoded (S503) in the way determined by the communication mode.

When a user wants to transmit digital data during communication, the signal for digital data transmission is inputted (S504) in an interrupt form. The digital data is converted (S505) and inserted (S506) into the voice signal in the watermark form, and then the voice signal having the watermark inserted therein is transmitted (S507).

According to the transmitting method illustrated in FIGS. 4 and 5, the decoding process is embodied correspondingly. As the process of inserting the watermark is performed before and after the encoding process, the decoding process is similar to the process of inserting the watermark. In other words, the signal is decoded after the watermark is extracted or the watermark is extracted after signal is decoded.

As aforementioned, the method for digital data transmission in accordance with the present invention does not require an additional fee because a function of transmitting additional information such as a text message is performed via a voice channel during communication without using an additional protocol. The function is used as an additional function of the mobile phone such as exchanging a memo during communication, and used as a function of transmitting an advertising message.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for digital data transmission by using a mobile communication device, comprising the steps of:
converting the analog voice signal inputted through the microphone into the digital signal;
inserting digital data in a watermark form into the converted digital voice signal; and
encoding the digital voice signal having a watermark inserted therein by converting the signal in a way determined by a communication mode; and
transmitting encoded voice signal having the watermark inserted therein.

2. The method of claim 1, wherein the digital data inserted into the digital voice signal is additional service data being used in a mobile communication system.

3. The method of claim 2, wherein the additional information service data is at least one of a short message service (SMS), an enhanced messaging service (EMS), and a multimedia messaging service (MMS).

4. A method for digital data transmission by using a mobile communication device, comprising the steps of:
converting the analog voice signal inputted through the microphone into the digital signal;
inserting a watermark into the digital voice signal, the watermark including digital data in accordance with additional information service;
encoding the digital voice signal having the watermark inserted therein in a way determined by the communication mode; and
transmitting encoded voice signal having the watermark inserted therein.

5. The method of claim 4, wherein the additional service data is at least one of a short message service (SMS), an enhanced messaging service (EMS), and a multimedia messaging service (MMS).

6. A method for digital data transmission by using a mobile communication device, comprising the steps of:
converting an analog voice signal inputted through a microphone into a digital signal;
encoding the digital voice signal in a way determined by communication mode;
inserting a watermark into the encoded digital voice signal, the watermark including digital data in accordance with additional information service; and
transmitting the encoded voice signal having the watermark inserted therein.

7. The method of claim 6, wherein the additional service data is at least one of a short message service (SMS), an enhanced messaging service (EMS), and a multimedia messaging service (MMS).

8. An apparatus for digital data transmission by using a mobile communication device, comprising:
an analog-digital converter for converting an analog voice signal inputted through a microphone into a digital signal;
a voice encoder for creating an encoded voice signal thorough compressing and encoding a voice signal digitized through the analog-digital converter;
a watermark inserting member for inserting digital data in a watermark form into the encoded voice signal; and
a transmitter for transmitting the voice signal having the watermark inserted therein.

9. The apparatus of claim 8, wherein the digital data is additional information service data being used in the mobile communication system.

10. The apparatus of claim 9, wherein the additional information service data is at least one of a short message service (SMS), an enhanced messaging service (EMS), and a multimedia messaging service (MMS).

11. An apparatus for digital data transmission by using a mobile communication terminal, comprising:
an analog-digital converter for converting an analog voice signal inputted through a microphone into a digital signal;
a watermark inserting member for inserting digital data into a digital voice signal in a watermark form;
a voice encoder for creating an encoded voice signal by compressing and encoding the voice signal having the watermark inserted therein;
a transmitter for transmitting the encoded voice signal having the watermark inserted therein.

12. The apparatus of claim 11, wherein the digital data is additional information service data being used in a mobile communication system.

13. The apparatus of claim 12, wherein the additional information service data is at least one of a short message service (SMS), an enhanced messaging service (EMS), and a multimedia messaging service (MMS).
